(19) United States
(12) Patent Application Publication
(10) Pub. No.: US 2005/0253627 A1
(43) Pub. Date: Nov. 17, 2005

(54) Multi level fixed parameter assignment

(76) Inventor: George R. Claseman, Campbell, CA (US)

Correspondence Address: PATENT LAW GROUP LLP, 2635 NORTH FIRST STREET, SUITE 223, SAN JOSE, CA, 95134, US

(21) Appl. No.: 10/845,810

(22) Filed: May 13, 2004

(51) Int. Cl. H03K 19/00

(52) U.S. Cl. 326/101

(57) ABSTRACT

A method for assigning a value to a fixed parameter in an electrical device where the fixed parameter has three or more states includes associating a voltage value to each of the states of the fixed parameter where the voltage values are selected from between the positive and negative power supply voltages of the electrical device, receiving an input voltage on a first input terminal of the electrical device, determining the voltage value of the input voltage, and selecting a state for the fixed parameter based on the voltage value of the input voltage. The input voltage has a constant voltage value and is provided continuously to the input terminal of the electrical device when the electrical device is in use. The states of the fixed parameter can be associated with multiple operational modes of the electrical device or with address bits of a multi-bit addressing field.

### FIELD OF THE INVENTION

The invention relates to a method for fixed parameter assignment in an integrated circuit and, in particular, to a method for fixed parameter assignment using a reduced number of input/output pins.

### DESCRIPTION OF THE RELATED ART

Electrical devices or integrated circuits providing application specific functions often require assignment of values for certain fixed parameters on the devices upon start-up in order to operate in the application in which the devices are incorporated. Fixed parameter assignment is often used for address assignments, selecting a mode of operation, and selecting other fixed operating personality elements of the device. Examples of devices where mode selection is used are Ethernet devices using a large number of addressing pins for programming, hardware devices including one or more fixed operation modes, and digital and analog devices using SM bus (system management bus) addressing as the control and status interface. These devices are often designed with multiple operational personalities whereby one or a group of operational personalities are selected when the device is installed for use. The selected personalities are usually permanent to be used for the life-time of the device in the application.

In many integrated circuits, the desired mode or function is usually selected by programming one or more fixed parameters through one or more input/output (I/O) pins of the integrated circuit. A specific address, mode or personality is selected by assigning a specific value to a parameter in the integrated circuit in which the parameter is linked to the desired address, operation mode or personality. Conventional fixed parameter assignment is typically implemented using a binary strap option. That is, a pin is connected either to a logical high voltage or a logical low voltage to select one of two possible states for a predefined parameter.

When a parameter is linked to multiple choices or is associated with long fields, multiple I/O pins will be required to implement fixed parameter value assignment when the binary strap method is used. Excessive pin count is undesirable as it results in increased material and manufacturing cost. Alternate methods exist for assigning values to fixed parameters on an electrical device, but generally these alternate methods require an additional external storage device.

It is desirable to provide a method for fixed parameter assignment using minimum I/O pins.

### SUMMARY OF THE INVENTION

According to one embodiment of the present invention, a method for assigning a value to a fixed parameter in an electrical device where the fixed parameter has three or more states includes associating a voltage value to each of the three or more states of the fixed parameter where the voltage values are selected from between the positive power supply voltage and the negative power supply voltage of the electrical device, receiving an input voltage on a first input terminal of the electrical device, determining the voltage value of the input voltage, and selecting a state for the fixed parameter based on the voltage value of the input voltage. The input voltage has a constant voltage value and is provided continuously to the input terminal of the electrical device when the electrical device is in use.

In one embodiment, the three or more states of the fixed parameter are associated with three or more operational modes of the electrical device. In another embodiment, each of the three or more states of the fixed parameter is associated with an address bit of a multi-bit addressing field.

The present invention is better understood upon consideration of the detailed description below and the accompanying drawings.

### BRIEF DESCRIPTION OF THE DRAWINGS

FIG. 1 is a schematic diagram of an electrical device employing the fixed parameter value assignment method according to one embodiment of the present invention.

FIG. 2 is a schematic diagram of an electrical device employing the fixed parameter value assignment method according to an alternate embodiment of the present invention.

### DETAILED DESCRIPTION OF THE PREFERRED EMBODIMENTS

In accordance with the principles of the present invention, a method for fixed parameter assignment uses one or more fixed voltage levels to program various fixed aspects of an electrical device. The method minimizes the number of input/output pins that are required to program multiple fixed parameters or fixed parameters including long programming fields.

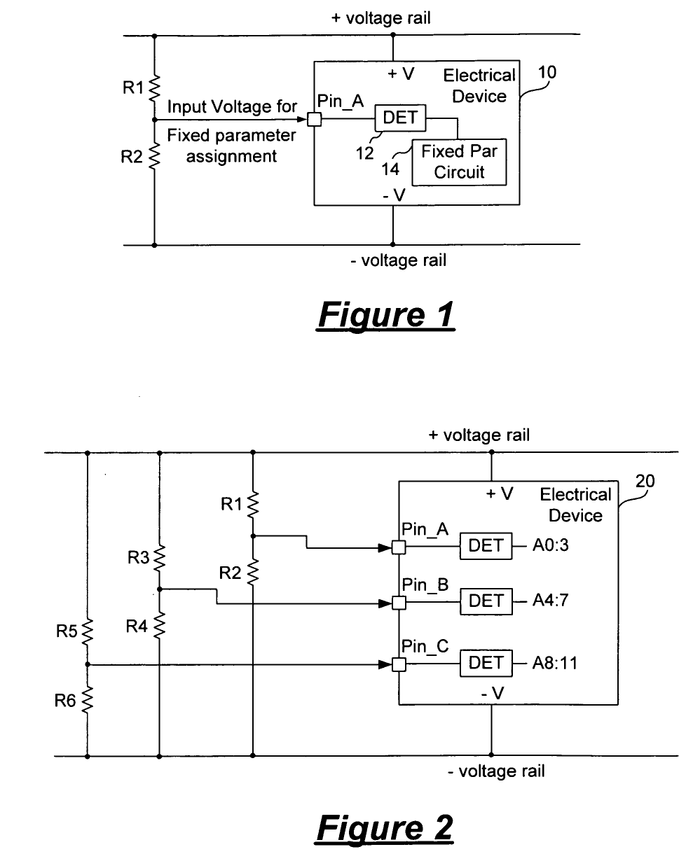

FIG. 1 is a schematic diagram of an electrical device employing the fixed parameter value assignment method according to one embodiment of the present invention. Referring to FIG. 1, an electrical device 10 is incorporated in a system for performing an application specific function. Electrical device 10 includes input/output terminals (not shown) for receiving incoming signals from and providing output signals to other components in the system. Electrical device 10 can be an integrated circuit in which case the input/output terminals are typically referred to as input/output (I/O) pins. When electrical device 10 is incorporated in a system for normal operation, the device is coupled to a positive voltage rail providing a positive power supply voltage (+V) and a negative voltage rail providing a negative power supply voltage (−V). Typically, the positive power supply voltage is referred to as the Vdd voltage and can be between 3.3 and 5 volts while the negative power supply voltage is referred to as the Vss voltage and is usually the ground voltage (0 volts).

The fixed parameter assignment method of the present invention uses multiple discrete voltage levels on an I/O pin to represent the programming states of a fixed parameter. The multiple discrete voltage levels are chosen between the positive power supply voltage and the negative power supply voltage of the electrical device. In operation, the desired state for the fixed parameter is indicated by the use of one of the multiple discrete voltage levels on an I/O pin of the electrical device. The selected state of the fixed parameter can be used to select one of several operation modes on device 10 or used to assign an address value for an address field in device 10. In the present embodiment, electrical device 10 includes an I/O pin PIN_A designated for fixed parameter assignment. PIN_A receives an input voltage from an external source having a voltage value indicative of the desired state to be programmed for the fixed parameter associated with PIN_A.

In one embodiment, electrical device 10 includes a voltage detector 12 coupled to PIN_A and a fixed parameter circuit 14 coupled to the voltage detector. Voltage detector 12 measures the voltage value on the I/O pin and provides an output signal indicative of the input voltage value. The output signal can then be used by fixed parameter circuit 14 to select a desired state for the fixed parameter associated with PIN_A. The number of discrete levels that can be programmed onto a single I/O pin is based on the level variations that the voltage detector can detect. That is, more voltage levels can be detected when a more precise voltage detector is used. Thus, a single pin can be used to select one of multiple operational modes as long as a voltage detector having the requisite voltage detection precision is used.

The discrete voltage levels to be assigned as states of the fixed parameter can be evenly distributed or randomly distributed between the positive power supply voltage and the negative power supply voltage. For most applications, it is usually convenient to provide a number of levels that are in powers of 2 but this is not a requirement for practicing the present invention.

In one embodiment, voltage detector 12 is an analog voltage detector designed to detect four voltage levels. Thus, the fixed parameter associated with PIN_A can be programmed to four different states designated in binary as “00”, “01”, “10” and “11”. For example, if the input voltage is greater than the first two voltage levels but less than the third voltage level, then an output signal having a binary value of “10” is provided by the voltage detector. If the input voltage is greater than the first three voltage levels, then a binary output value of “11” is provided. The binary value can be provided to fixed parameter circuit 14 to select the desired programming state.

The input voltage is typically provided by the user outside of the electrical device. For example, as shown in FIG. 1, a voltage divider formed using commonly available resistors can be used to program a desired input voltage value. The input voltage is typically provided to electrical device 10 continuously when device 10 is in use or powered up. In this manner, the desired operational mode or address values is permanently programmed on the electrical device.

For large addressing fields, groups of address bits can be assigned using a single I/O pin. For example, if a voltage detector capable of detecting 8 voltage levels is used in an electrical device, then each I/O pin can be used to program three bits of an addressing field. FIG. 2 is a schematic diagram of an electrical device employing the fixed parameter value assignment method according to an alternate embodiment of the present invention. Referring to FIG. 2, a 12-bit address field is being programmed using three I/O pins. Each I/O pin is coupled to receive a respective input voltage. Each I/O pin is coupled to a voltage detector capable of detecting sixteen different voltage levels. Thus, each I/O pin can be used to program 4 bits of the address field and a total of only 3 pins are required for the 12-bit address field. Significant pin saving is realized as compared to the conventional binary assignment approach as 12 pins are typically used to program the 12-bit address.

In other applications, complex internal states can be narrowed down to a smaller subset of possibilities which are defined by the external state assignment. The complexity of implementing the parameter assignment function can thus be simplified.

The above detailed descriptions are provided to illustrate specific embodiments of the present invention and are not intended to be limiting. Numerous modifications and variations within the scope of the present invention are possible. The present invention is defined by the appended claims.

1. A method for assigning a value to a fixed parameter in an electrical device, the fixed parameter having three or more states, the method comprising:
associating a voltage value to each of the three or more states of the fixed parameter, the voltage values being selected from between the positive power supply voltage and the negative power supply voltage of the electrical device;
receiving an input voltage on a first input terminal of the electrical device, the input voltage having a constant voltage value and being provided continuously to the input terminal of the electrical device when the electrical device is in use;
determining the voltage value of the input voltage; and
selecting a state for the fixed parameter based on the voltage value of the input voltage.

2. The method of claim 1, wherein the three or more states of the fixed parameter are associated with three or more operational modes of the electrical device.

3. The method of claim 1, wherein each of the three or more states of the fixed parameter is associated with an address bit of a multi-bit addressing field.

4. An electrical device including a fixed parameter to be programmed when the electrical device is in use, the electrical device comprising:
a fixed parameter circuit receiving an input signal and providing an output signal indicative of a selected state for the fixed parameter having three or more states, the fixed parameter circuit associating a voltage value to each of the three or more states of the fixed parameter, the voltage values being selected from between the positive power supply voltage and the negative power supply voltage of the electrical device;
an input terminal coupled to receive an input voltage, the input voltage having a constant voltage and being provided continuously to the input terminal of the electrical device when the electrical device is in use; and
a voltage detector coupled to the input terminal for receiving the input voltage and providing a signal indicative of the voltage value of the input voltage to the fixed parameter circuit as the input signal of the fixed parameter circuit,
wherein the fixed parameter circuit selects a state for the fixed parameter based on the voltage value of the input voltage.

5. The electrical device of claim 4, wherein the three or more states of the fixed parameter are associated with three or more operational modes of the electrical device.

6. The electrical device of claim 4, wherein each of the three or more states of the fixed parameter is associated with an address bit of a multi-bit addressing field.
